(19) United States
(12) Patent Application Publication
(10) Pub. No.: US 2014/0295138 A1
(43) Pub. Date: Oct. 2, 2014

(54) HIGH PERFORMANCE TEXTURED PIEZOELECTRIC CERAMICS AND METHOD FOR MANUFACTURING SAME

(71) Applicants: Yongke Yan, Blacksburg, VA (US); Shashank Priya, Blacksburg, VA (US)

(72) Inventors: Yongke Yan, Blacksburg, VA (US); Shashank Priya, Blacksburg, VA (US)

(73) Assignee: Virginia Tech Intellectual Properties, Inc., Blacksburg, VA (US)

(21) Appl. No.: 14/351,803

(22) PCT Filed: Oct. 12, 2012
(86) PCT No.: PCT/US12/60013

§ 371 Date: Apr. 14, 2014

Related U.S. Application Data
(60) Provisional application No. 61/546,107, filed on Oct. 12, 2011.

(51) Int. Cl. H01L 41/43; C30B 1/04; H01L 41/18

(52) U.S. Cl. CPC H01L 41/43; H01L 41/183; C30B 1/04
USPC 428/141; 117/7

(57) ABSTRACT

A textured PMN-PZT ceramic is created using templated grain growth to align seed crystals in a ceramic matrix powder by tape-casting process. Heat treatment then results in the nucleation and growth of matrix crystals on aligned templates. The resulting textured PMN-PZT ceramic has high longitudinal piezoelectric coefficient and a high piezoelectric voltage coefficient. In another embodiment, a textured PMN-PT ceramic has a volume fraction of the templates no greater than 1%. The utility of this invention includes both its exceptional piezoelectric properties as well as the utilization of an economical manufacturing process that is widely used in the multi-layer ceramic capacitor industry.

### REFERENCE TO RELATED APPLICATION

The present application claims the benefit of U.S. Provisional Patent Application No. 61/546,107, filed Oct. 12, 2011, whose disclosure is hereby incorporated by reference in its entirety into the present disclosure.

### STATEMENT OF GOVERNMENT INTEREST

The present invention was made under DARPA Grant No. FA8650-09-1-7945. The government has certain rights in the invention.

### FIELD OF THE INVENTION

The present invention is directed to piezoelectric crystals and more particularly to piezoelectric crystals using textured polycrystals. The present invention is further directed to methods of manufacturing such crystals.

### DESCRIPTION OF RELATED ART

Conversion of mechanical energy to electrical energy or vice versa via the electromechanical coupling effect in piezoelectric materials provides a wide range of transducer applications. The performance of piezoelectric materials is generally characterized by piezoelectric coefficients d (piezoelectric charge or strain constant) determining how much output charge or strain can be generated when the input mechanical stress or electric field is applied to the materials, g (piezoelectric voltage constant) determining how much output electric field can be generated when the input mechanical stress is applied to the materials, and k (electromechanical coupling constant) implying how effectively the materials convert input mechanical (or electrical) energy to output electrical (or mechanical) energy. The constant d is of importance for strain-dependent applications such as medical ultrasonic imaging, sonar transducers and solid-state actuators. The g constant is a measure for assessing a material's suitability for sensing applications such as pressure/stress sensors. Recently, as attention to piezoelectric energy harvesting research has increased, the constant d·g has become an important figure of merit for the high energy density of piezoelectric materials.

Since the composition Pb(Zr,Ti)O₃ was discovered in the mid 1950's, much investigation has been conducted on developing high performance piezoelectric materials. As a result of such investigation, it is known that [001] oriented relaxor-based piezoelectric single crystals such as Pb(Mg_{1/3}Nb_{2/3})O₃—PbTiO₃ (PMN-PT) and Pb(Zn_{1/3}Nb_{2/3})O₃—PbTiO₃ (PZN-PT) with compositions near the morphotropic phase boundary (MPB) exhibit a large d₃₃ of >2000 pC/N and k₃₃ of >92% with engineered domain configurations that facilitate the orientation of polarization along the [001] direction. An example is shown in FIG. 1A, in which a single crystal 102 having a crystal lattice 104 in a [001] direction 106 is sandwiched between electrodes 108, 110 to form a transducer 100. However, the low ferroelectric rhombohedral to tetragonal phase transition temperature (T_{R-T}˜60-100° C.) and Curie temperature (T_{C}˜130-170° C.) and low coercive fields (E_{C}˜2-3 kV/cm) of these relaxor-based crystals limit their applications where the thermal and electrical stability of piezoelectric properties is critical. Recently, [001] oriented Pb(Mg_{1/3}Nb_{2/3})O₃—PbZrO₃—PbTiO₃ (PMN-PZT) single crystals have been reported to exhibit an improved piezoelectric stability representing higher T_{R-T}, T_{C} and E_{C} than those of PMN-PT or PZN-PT single crystals with excellent piezoelectric properties.

The superior piezoelectric properties of [001] oriented single crystals are hardly observed in randomly oriented polycrystalline ceramics in which piezoelectric properties along the [001] direction are averaged out by randomly distributed crystalline grains. An example is shown in FIG. 1B, in which a polycrystalline ceramic 112 composed of multiple grains 114, each having a different crystal lattice 116 oriented in a different [001] direction 118, is incorporated into a transducer 100′. However, piezoelectric single crystals usually involve costly fabrication processes (high temperature annealing for a long time), as compared to conventional polycrystalline ceramic processes. Also, the size limit of crystal products restricts industrial applications, especially where large dimension components are required.

One good strategy to overcome the cost and size drawbacks of single crystals and achieve high performance piezoelectric materials is the [001] texturing of piezoelectric ceramics (grain orientation along the [001] crystallographic direction) to make an engineered domain state similar to that of a [001] oriented single crystal. An example is shown in FIG. 1C, in which a textured piezoelectric ceramic 120 composed of multiple grains 122, each grown around a seed (template) crystal 124, is incorporated into a transducer 100″. As a result of the texturing, the grains 122 have lattices 126 aligned along a single [001] direction 106, similarly to the single crystal 120 of FIG. 1A. Such texturing is done by a known technique called templated grain growth (TGG). The TGG process has been used to produce textured PMN-PT ceramics.

The TGG process will be explained with reference to the flow chart of FIG. 1D. The powders that will be formed into the matrix crystals are ball-milled with a binder and solvent in step 130. In step 132, the template crystals are added. In step 134, the resulting mixture is tape-cast to align the template crystals. The resulting layers are laminated in step 136 and heat cast in step 138 to form the textured ceramic in step 140.

The [001] textured PMN-PT ceramics showed highly enhanced piezoelectric properties compared with those of their random counterparts, but low T_{C} and E_{C} are still problematic for thermal and electrical stability. Moreover, most prior research on texturing piezoelectric ceramics has focused on increasing d₃₃ and has ignored g₃₃.

Another issue is that the design of piezoelectric materials faces constraints that appear to be mutually exclusive. One of the important issues in high power piezoelectric devices is heat generation under large AC resonant drives that significantly affects the device performance. In order to withstand the degradation under high power conditions, the piezoelectric material should possess high mechanical quality factor (Qₘ) and low dielectric loss (tan δ) along with high phase transition temperatures. In addition, a high electromechanical coupling coefficient (k) is necessary for effective electric to mechanical energy conversion, and a high strain coefficient (d) is important for high vibration velocity (vᵣₘₛ∝Qₘ·d). Therefore, designing high power piezoelectric materials involves consideration of “hard” and “soft” combinatory characteristics. These combinatory characteristics are also of importance in designing magnetoelectric (ME) laminate composites operating in the vicinity of electromechanical resonance. The realization of a piezoelectric material with “hard” and “soft” combinatory properties is quite challenging since the “hard” characteristics (high Qₘ and low tan δ) originate from a “pinned” ferroelectric domain state, which usually degrades the “soft” characteristics (high d and high k) of piezoelectrics.

Yet another issue is the effect of heterogeneous templates. As noted, templated grain growth (TGG) has proven to be a cost effective process for fabricating crystallographically oriented high performance piezoelectric ceramics, such as lead-free (Bi₁₋ₓNaₓ)TiO₃ (BNT) based, (K₁₋ₓNaₓ)NbO₃ (KNN) based, and lead-based Pb(Mg_{1/3}Nb_{2/3})O₃—PbTiO₃ (PMN-PT) compositions. For texturing PMN-PT ceramic, perovskite BaTiO₃ (BT) and SrTiO₃ (ST), which have the same crystallographic structure with similar lattice parameters and can be synthesized into well-faceted high-aspect ratio crystallites, have been chosen as substitution. However, heterogeneous templates inevitably degrade the performance of sintered ceramic mainly because of interfacial diffusion and stress clamping between matrix and templates. For example, dissolution of the ST template in PMN-PT results in an unacceptably low depolarization temperature (˜60° C.). The BT template is stable in PMN-PT, but residual templates reduce the strain response of textured ceramics via mechanical clamping.

### SUMMARY OF THE INVENTION

A need thus exists in the art to overcome the above limitations.

It is therefore an object of the invention, in at least some embodiments, to provide a piezoelectric ceramic with improved thermal and electrical stability.

It is another object of the invention, in at least some embodiments, to provide a piezoelectric ceramic with improved d₃₃ and g₃₃.

It is still another object of the invention, in at least some embodiments, to improve both hard and soft characteristics.

To achieve the above and other objects, the present invention in at least one embodiment is directed to a [001] textured PMN-PZT ceramic. The d₃₃ value of textured sample was ˜5 times (the highest increasing rate among reported values to date) higher than that of randomly oriented counterpart. Excellent piezoelectric properties (d₃₃˜1100 pC/N and k_{P}˜0.85) with high T_{C}˜204° C. and E_{C}˜8.4 kV/cm were achieved from our textured ceramic with even much higher voltage constant (g₃₃˜53.8×10⁻³ Vm/N) than single crystal value. The textured PMN-PZT ceramic with high d and high g is believed to open a new piezoelectric application area along with its economical fabrication process.

A variation of the first preferred embodiment uses Mn-doping and takes advantage of the electromechanical properties of a textured ceramic such as 0.4Pb(Mg_{1/3}Nb_{2/3})O₃-0.25PbZrO₃-0.35PbTiO₃ (PMN-PZT), which has a relatively high rhombohedral to tetragonal (R—T) transition temperature (T_{R-T} of 160° C.) and a Curie temperature (T_{C} of 234° C.). It was found that MnO₂-doped textured PMN-PZT ceramics with 5 vol. % BaTiO₃ template (T-5BT) exhibited inferior temperature stability. The coupling factor (k₃₁) of T-5BT ceramic started to degrade from 75° C., while the random counterpart showed a very stable tendency up to 180° C. This degradation was associated with the “interface region” formed in the vicinity of the BT template. MnO₂ doped PMN-PZT ceramics textured with 3 vol. % BT and subsequently poled at 140° C. (T-3BT140) exhibited very stable and high k₃₁ (>0.53) in a wide temperature range from room temperature to 130° C. through reduction in the interface region volume. Further, the T-3BT140 ceramic exhibited excellent hard and soft combinatory piezoelectric properties of d₃₃=720 pC/N, k₃₁=0.53, Qₘ=403, tan δ=0.3%, which are very promising for high power and magnetoelectric applications.

In a second preferred embodiment, [001]-textured Pb(Mg_{1/3}Nb_{2/3})O₃—PbTiO₃ (PMN-PT) ceramics were synthesized by using the templated grain growth method. A significantly high [001] texture degree, corresponding to a 0.98 Lotgering factor, was achieved at 1 vol. % BaTiO₃ template. Electromechanical properties for [001]-textured PMN-PT ceramics with 1 vol. % BaTiO₃ were found to be d₃₃=1000 pC/N, d₃₁=371 pC/N, δᵣ=2591, and tan δ=˜0.6%. Elastoelectric composite based modeling results showed that higher volume fraction of template reduces the overall dielectric constant and thus has adverse effect on the piezoelectric response. The clamping effect was modeled by deriving the changes in free energy as a function of applied electric field and microstructural boundary condition

The following articles give further details of the invention and are hereby incorporated by reference in their entireties into the present disclosure:

Yongke Yan et al, “Electromechanical behavior of [001]-textured Pb(Mg_{1/3}Nb_{2/3})O₃—PbTiO₃ ceramics,” Applied Physics Letters 100, 192905 (2012); and

Yongke Yan et al, “Piezoelectric properties and temperature stability of Mn-doped Pb(Mg_{1/3}Nb_{2/3})—PbZrO₃—PbTiO₃ textured ceramics,” Applied Physics Letters 100, 132908 (2012).

### BRIEF DESCRIPTION OF THE DRAWINGS

Preferred embodiments of the present invention will be set forth in detail with reference to the drawings, in which:

FIG. 1A is a schematic diagram of a transducer having a piezoelectric single crystal;

FIG. 1B is a schematic diagram of a transducer having a randomly oriented piezoelectric polycrystal;

FIG. 1C is a schematic diagram of a transducer having a textured piezoelectric polycrystal;

FIG. 1D is a flow chart of the TGG process;

FIG. 2A is a scanning electron microscope image of BaTiO₃ seed crystals;

FIG. 2B is a graph showing the Lotgering factor as a function of sintering temperature;

FIG. 2C is a scanning electron microscope image of a fractured surface of textured PMN-PZT sintered at 1150° C.;

FIG. 2D is a graph of XRD patterns of randomly oriented and textured PMN-PZT sintered at 1150° C.;

FIG. 2E is a photograph of textured PMN-PZT samples sintered at 1150° C.;

FIG. 3A is a graph of g₃₃ as a function of d₃₃ for various piezoelectric compositions;

FIG. 3B is a graph of the relation between d₃₃ for randomly oriented ceramics and that for textured ceramics for various piezoelectric compositions;

FIG. 4 is a graph of dielectric and piezoelectric loses of randomly oriented and textured PMN-PZT ceramics as a function of frequency;

FIG. 5 is a flow chart showing the steps in the manufacturing method according to the preferred embodiment;

FIG. 6 is a graph showing the difference in strain between textured and random ceramic materials;

FIG. 7A is a graph of XRD patterns of randomly oriented and textured MnO₂ doped PMN-PZT ceramics with 5 vol.% BT template (abbreviated as R and T-5BT, respectively);

FIG. 7B is a SEM image of T-5BT ceramic;

FIG. 7C is a SEM image of R ceramic;

FIG. 7D is a graph of line scanning element analysis of EDS across BT and PMN-PZT matrix;

FIG. 8A is a graph of the dielectric constant (∈₃₃^{T}/∈₀) of R and T-5BT ceramic as a function of temperature;

FIG. 8B is a graph of the electromechanical coupling coefficient (k₃₁) of R and T-5BT ceramic as a function of temperature;

FIG. 9A is a graph of pyroelectric current vs. temperature curves of R and T-5BT ceramics poled at room temperature;

FIG. 9B is a graph of pyroelectric current vs. temperature curves of T-5BT ceramics poled at room temperature and 140° C.;

FIG. 9C is a graph of d₃₃ of R and T-5BT ceramics poled at room temperature and 140° C. as a function of annealing temperature;

FIG. 9D is a SEM image of partially dissolved BT template;

FIG. 9E is a schematic diagram of the concentration gradient that exists in the vicinity of the template—matrix interface;

FIG. 9F is a graph of the effect of the poling temperature and template content on degree of poling condition;

FIG. 10A is a graph of k₃₁ vs. temperature characteristics of randomly oriented and textured MnO, doped PMN-PZT ceramics with 1, 3, and 5 vol. % BT template poled at 140° C. (abbreviated as R, T-1BT140, T-3BT140, and T-5BT140, respectively);

FIG. 10B is a graph of the Lotgering factor (f), degradation temperature (T_{de}), d₃₃ and k₃₁ of textured MnO, doped PMN-PZT ceramics as a function of BT template content;

FIG. 11A is a graph of XRD patterns of PMN-PT-xBT ceramics;

FIG. 11B is a graph of the texture degree of PMN-PT ceramics as a function of BT concentration;

FIG. 11C is a cross-sectional SEM image of PMN-PT-1BT ceramic;

FIG. 11D is a cross-sectional SEM image of PMN-PT-0BT ceramic;

FIGS. 12A and 12B are graphs of dielectric and piezoelectric properties of PMN-PT-xBT ceramics;

FIG. 12C is a graph of dielectric permittivity as a function of temperature for PMN-PT-xBT ceramics;

FIG. 12D is a graph of polarization (P) vs. electric field, (E) hysteresis loops;

FIG. 12E is a graph of XRD patterns of PMN-PT-xBT ceramics;

FIG. 13A is a schematic illustration of grains of textured ceramic;

FIG. 13B is a graph of required growth distance (x) of a matrix (solid line) and a specific interface area (Aᵢ/V) (dashed line) as a function of the volume fraction and dimensions of the template;

FIG. 13C is a schematic illustration of a single templated grain;

FIG. 13D is a graph of calculated relative permittivity of fully textured PMN-PT ceramic as a function of the volume fraction and dimensions of BT template; and

FIG. 14 is a graph of a theoretical prediction of dielectric and piezoelectric properties of textured PMN-PT ceramics as a function of BT template volume fraction.

### DETAILED DESCRIPTION OF THE PREFERRED EMBODIMENTS

Preferred embodiments of the present invention will now be disclosed with reference to the drawings, in which like reference numerals refer to like elements or steps throughout.

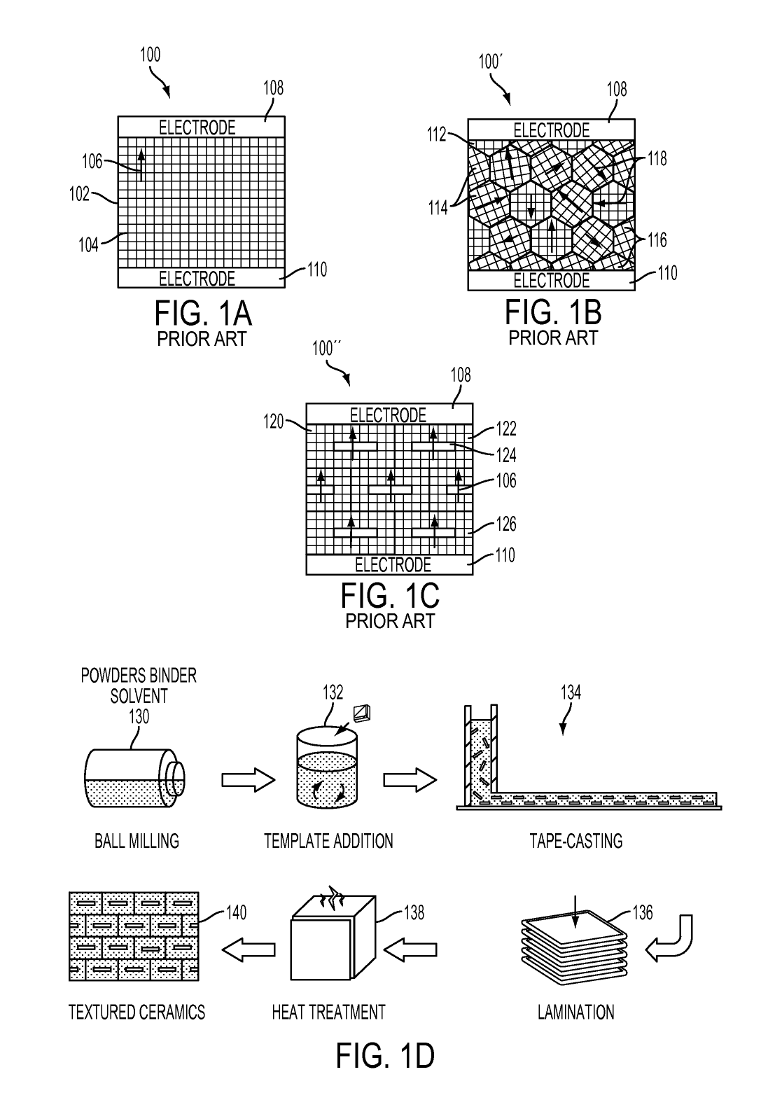

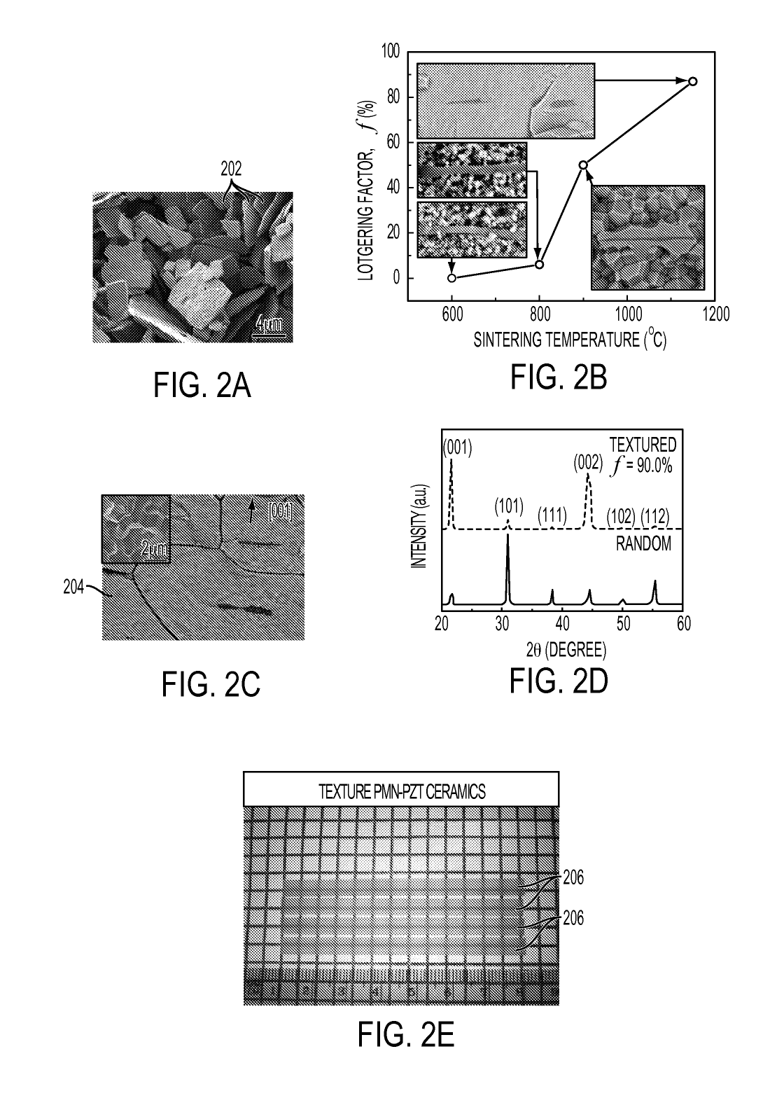

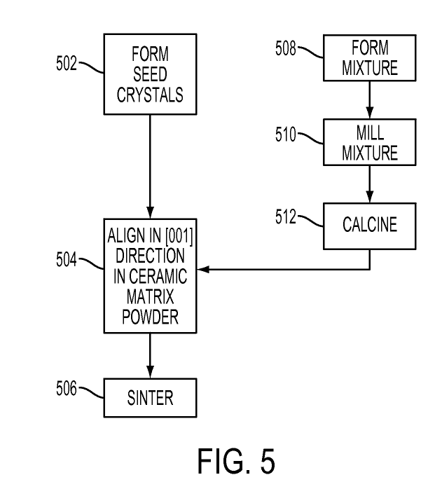

In the first preferred embodiment, the textured PMN-PZT ceramic with a chemical composition of 0.4Pb(Mg_{1/3}Nb_{2/3})O₃-0.25PbZrO₃-0.35PbTiO₃ was prepared by the TGG process, which will be explained with reference to the flow chart of FIG. 5. In the TGG process, seed crystals (or templates) are formed or otherwise provided in step 502 and aligned in step 504 in a ceramic matrix powder by a tape-casting process, which is economical and has been widely used in the multi-layer ceramic capacitor industry. Then, heat treatment (or sintering) in step 506 results in the nucleation and growth of matrix crystals on aligned templates, yielding textured ceramics, as shown in FIG. 1C. The crystallographic orientation of grown matrix crystals is strongly dependent upon that of seed crystals. In order to achieve highly [001] textured ceramics, the seed crystals should possess a thin platelet morphology with a (001) plane to facilitate their homogeneous alignment in the matrix and crystal growth along the [001] direction. We selected BaTiO₃ (BT) as a seed composition due to its chemical stability in PMN-containing ceramics and good lattice match with the PMN-PZT composition (˜4.05 Å). By a topochemical microcrystal conversion technique, compositionally pure BT seed crystals with desirable morphology were synthesized, as shown in FIG. 2A as element 202. After embedding 5 vol % BT seed crystals, the PMN-PZT ceramic was subjected to different sintering temperatures. As shown in FIG. 2B, the Lotgering factor, implying the [001] texture degree, was calculated by using XRD peaks of sintered specimens. With increasing sintering temperature, the crystal growth of matrix PMN-PZT on the BT seed became clear without any trace of reaction problems between seed and matrix. A high [001] Lotgering factor of 90% with a highly textured microstructure was observed from the specimen sintered at 1150° C., as shown in FIGS. 2C and 2D. Note that this highly textured PMN-PZT was achieved by only 2 hours of sintering at a reasonably low temperature of 1150° C. (same as the sintering condition of random-polycrystalline PMN-PZT ceramic). Furthermore, over 70 mm-long textured specimens were confirmed to be easily fabricated by our lab-scale processing as shown in FIG. 2E as element 206, demonstrating their readiness for industrial mass production with size-free and economical fabrication.

Table 1 below displays piezoelectric and dielectric properties of randomly oriented polycrystalline ceramic (R-ceramic), [001] textured ceramic (T-ceramic), and [001] single crystal for the same PMN-PZT composition.

TABLE 1

| | | | Single |
|---|---|---|---|
| Properties | R-ceramic | T-ceramic | crystal |
| Piezoelectric charge constant, d₃₃ (pC/N) | 230 | 1100 | 1530 |
| Piezoelectric voltage constant, g₃₃ (×10⁻³ | 28.4 | 53.8 | 35.6 |
| Vm/N) | | | |
| Electromechanical coupling constant, kₚ | 0.4 | 0.84 | 0.93 |
| Relative dielectric permittivity, ε₃₃/ε₀ | 915 | 2310 | 4850 |
| Remanent polarization, Pᵣ (μC/cm²) | 27.8 | 36.1 | 29 |
| Coercive field, E_{c} (kV/cm) | 9.2 | 8.4 | 4.5 |
| Curie temperature, T_{C} (° C.) | 233 | 204 | 211 |

The T-ceramic showed 378%, 89.4% and 110% increased d₃₃, g₃₃ and k_{P} values, respectively, as compared to those of R-ceramic demonstrating marvelous texturing effect. Especially, the g₃₃ value of the T-ceramic was as high as 53.8×10⁻³ Vm/N, much higher even than that of single crystal, resulting in a very high d₃₃·g₃₃ constant of 59180×10⁻¹⁵ m²/N (the highest value reported to date).

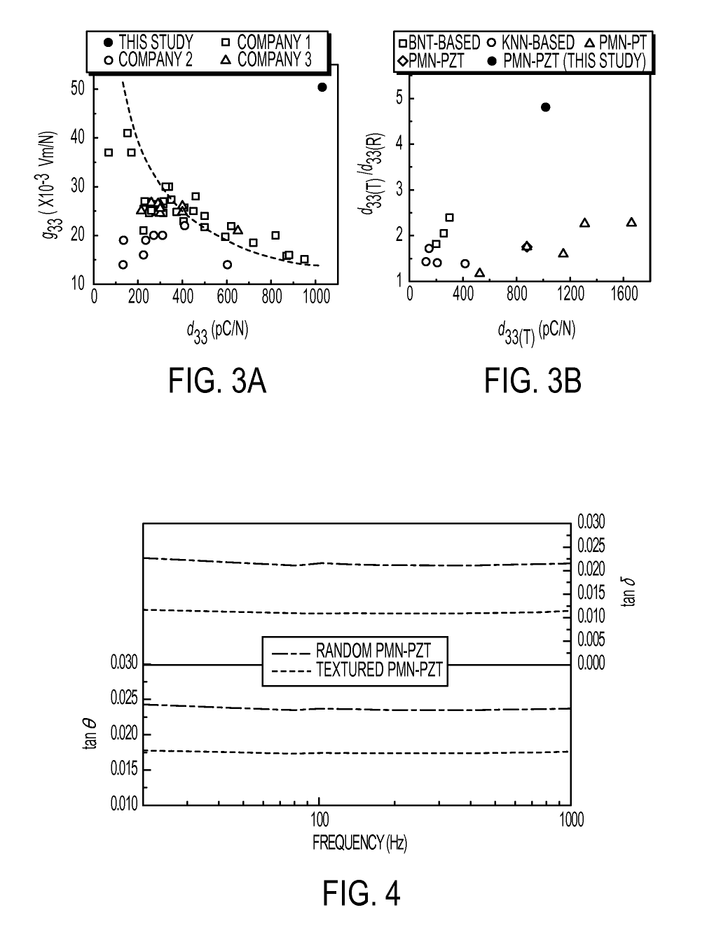

It should be noted that high d and high g are difficult to achieve at the same time from a single piezoelectric material due to the relation g=d/∈, where dielectric permittivity ∈=d²Y/dk² (Y=Young's modulus). Generally, an increase in d is accompanied by a much more increased ∈, resulting in decreased g, and the relation g∝d⁻¹ can be empirically suggested for different compositions. That tendency is observed from commercially available piezoelectric materials, as shown in FIG. 3A. It can be obviously seen from FIG. 3A that materials having high d₃₃ show low g₃₃, while high g₃₃ compositions possess low d₃₃.

However, the T-ceramic exhibited both high d₃₃ and high g₃₃, representing its superiority to the existing piezoelectric ceramics for a wide range of piezoelectric applications. We believe that the realization of this high performance of T-ceramic is mainly due to the existence of BT seed crystals. The high d₃₃ of T-ceramic could be achieved by BT seed-associated [001] texturing effect. Meanwhile, the T-ceramic obtained by TGG is considered as a composite material composed of PMN-PZT matrix and monodispersed BT seed crystals aligned perpendicularly to the [001] direction (a lamellae composite structure in an exaggerated manner). Therefore, the dielectric characteristics of T-ceramic are possibly affected by those of each PMN-PZT and BT component. The effective permittivity of lamellae composite is expressed by

$$ɛ = \sqrt{\frac{f {ɛ}_{i} + ( 1 - f ) {ɛ}_{m}}{\frac{f}{{ɛ}_{i}} + \frac{1 - f}{{ɛ}_{m}}}} , \qquad ( 1 )$$

where ∈ᵢ and ∈ₘ are the permittivity of the dispersed inclusions and the matrix, respectively, and f is the volume fraction occupied by the inclusions. By taking relative permittivity values along the [001] direction of BT seeds (130) and a PMN-PZT single crystal (4850) into ∈ᵢ and ∈ₘ in Eq. (1), respectively, the relative permittivity of the composite was calculated to be 2819, which is reasonably close to that of T-ceramic as seen in Table 1. Therefore, with high d₃₃ and relatively low permittivity of T-ceramic, high g₃₃ can be achieved, as determined by the following equation:

$${g}_{33} = \frac{{d}_{33}}{{ɛ}_{33}} = 2 {Q}_{11} {P}_{3} , \qquad ( 2 )$$

where Q₁₁ is the electrostrictive constant of the paraelectric phase and typically varies between 0.05 and 0.1 m⁴/C² for different materials, and P₃ is the polarization along the polar axis and approximately equals Pᵣ. The relationship between g₃₃ and the polarization magnitude in Eq. (2) is corresponds well to the higher g₃₃ and Pᵣ values of T-ceramic than those of [001] single crystal, as seen in Table 1. Demonstrating the effectiveness for controlling dielectric characteristics as well as the engineering domain state of textured piezoelectric ceramics, the TGG process is considered an appropriate way to design piezoelectric materials suiting one's taste and needs.

Another interesting point is that the increasing ratio of d₃₃ between R- and T-ceramic is much higher than that of the other textured piezoelectric ceramics, as seen in FIG. 3B, which shows the ratio of d_{33(T)} to d_{33(R)} as a function of d_{33(T)}. The subscripts (T) and (R) refer to the values for the textured and randomly oriented ceramics. In most prior studies on textured piezoelectric ceramics, researchers selected MPB compositions where the piezoelectric properties of random polycrystalline ceramics are maximized. However, here we note that compositional discrepancy is observed between single crystals and random polycrystalline ceramics for optimum piezoelectric properties. The maximum d₃₃ value of PMN-PT ceramics was obtained from a 0.675PMN-0.325PT MPB composition, while a [001] oriented 0.7PMN-0.3PT single crystal with a rhombohedral-rich phase showed the maximum d₃₃. A similar result is also observed in BiScO₃—PbTiO₃ (BS-PT) systems. This trend implies that the domain state of single crystals with rhombohedral-rich phase is more effective for the piezoelectric effect than that with a MPB or tetragonal phase, representing that the MPB composition may not be the best candidate for [001]-textured piezoelectric ceramics. Our T-ceramic composition lies on the rhombohedral-rich side that facilitates polarization along the [001] direction, similarly to a [001] single crystal, by preventing the complex domain state of MPB, and that fact leads to the highest increasing rate in d₃₃ value of T-ceramic among reported textured compositions.

Next, we investigated loss factors of PMN-PZT ceramics. The losses of piezoelectric ceramics are related to hysteretic responses when the material is driven forward and backward simultaneously by an AC field. That nonlinear behavior is generally associated with the influence of mechanical and electrical stresses on ferroelectric domains. Dielectric loss (tan δ) of piezoelectric material represents electrical power loss and has been widely investigated as an important material parameter in the piezoelectric research field. However, piezoelectric loss (tan θ), the energy loss during piezoelectric conversion between mechanical and electrical energy, of piezoelectric materials has usually been ignored by researchers. The tan θ of piezoelectric material affects dynamic response of magnetoelectric effect along with tan δ, demonstrating the importance of these loss factors in piezoelectric applications, especially in the low frequency domain. The tan δ is easily measurable by using an LCR meter, and tan θ can be calculated by the following equation:

$$tan θ = \frac{tan δ + tan ϕ}{2} + \frac{1}{4} ( \frac{1}{{Q}_{r}} - \frac{1}{{Q}_{a}} ) [ 1 + {( \frac{1}{{k}_{31}} - {k}_{31} )}^{2} {Ω}_{a}^{2} ] , \qquad ( 3 )$$

where tan φ is the mechanical loss, Qᵣ and Qₐ are the mechanical quality factor at the resonance and antiresonance frequencies, respectively, and Ωₐ=πfₐl v⁻¹, fₐ is the antiresonance frequency, l is length and v is the sound velocity of a given piezoelectric material. The texturing effect on dynamic loss factors was clearly observed as shown in FIG. 4. By [001] texturing, both tan δ and tan θ of PMN-PZT ceramic were significantly decreased from 0.022 and 0.024 to 0.011 and 0.017, respectively. Furthermore, the losses of T-ceramic showed a very flat characteristic in a wide range of low frequencies, demonstrating its device stability at various operation frequency domains. The decreased losses, along with increased d₃₃ and g₃₃ values, are mainly attributed to the enhanced ability of the domain motion of T-ceramic and are very promising for high density energy harvester applications, as well as underlying various potential piezoelectric applications with a high d·g factor.

Experimental results will now be disclosed. BaTiO₃ (BT) platelets were used as a template for texturing PMN-PZT. The templates were synthesized by a topochemical microcrystal conversion method. First, Bi₄Ti₃O₁₂ platelets were synthesized by reacting Bi₂O₃ (99%, Alfa Aesar, Ward Hill, Mass.) and TiO₂ (99.5%+, Alfa Aesar) powders in NaCI (99.0%+, Alfa Aesar) and KCI (99%, Alfa Aesar) molten salts at 1050° C. for 1 h. Next, BaBi₄Ti₄O₁₅ platelets were synthesized by reaction of Bi₄Ti₃O₁₂, TiO₂, and BaCO₃ (99.8%, Alfa Aesar) in BaCl₂ (99%, Alfa Aesar)/KCl molten salts at 1050° C. for 3 h. Lastly, BT platelets were obtained by topochemical reaction between BaBi₄Ti₄O₁₅ and BaCO₃ in KCl molten salt at 950° C. for 3 h. In all those reactions, the weight ratio between reacting chemicals and salt(s) was maintained at 1:1. For matrix powders, 0.4Pb(Mg_{1/3}Nb_{2/3})O₃-0.25PbZrO₃-0.35PbTiO₃ (PMN-PZT) precursors were synthesized by a conventional solid state reaction. Referring back to FIG. 5, a mixture of (PbCO₃)₂Pb(OH)₂ (99.9%, Sigma Aldrich, St. Louis, Mo.), Nb₂O₅, ZrO₂, TiO₂, ZnO and MnO₂ was formed in step 508 and ball-milled in step 510 in ethanol for 72 h using stabilized ZrO₂ (Tosoh USA, OH) milling media. After drying, the mixture was calcined in step 512 at 700° C. for 1 h. Calcined powders with 1 wt % excess PbO were ball-milled again for 72 h. For tape casting, the slurries were prepared by mixing the PMN-PZT matrix powders with 5 vol % BT template platelets, organic binder (Ferro 73225, Vista, Calif.), and toluene/ethanol solvents. The slurries were cast at a rate of 40 cm/min by using a doctor blade with a height of 200 μm. The dried tapes were cut, stacked, and laminated at 70° C. under 20 MPa pressure for 15 min. The green samples were heated to 500° C. with a heating rate of 0.3° C./min for burning out the organic binder, and then isostatically pressed at 200 MPa for 5 min. To reduce PbO volatilization, the samples were embedded in calcined PMN-PZT powders containing 3 wt % excess PbO within a closed crucible. The samples were then heated with a heating rate of 10° C./min in flowing O₂ (0.2 L/min) ambient and sintered at 1150° C. for 2 h. The structural properties of textured samples were determined using x-ray diffraction (XRD, PANalytical X'Pert, CuKα, Philips). The degree of pseudo-cubic [001] texture was determined from the Logtering factor method. SEM (FEI Quanta 600 FEG, Philips) was used to analyze the morphology of the template and microstructure of the sintered samples. For electrical measurements, the sample surfaces were polished, and electrodes were formed from silver paste. All the samples were poled at 30 kV/cm for 15 min at room temperature. The dielectric permittivity and loss factor of poled samples was measured as a function of temperature by using a multi-frequency LCR meter (HP7274A). The polarization vs. electric field hysteresis was measured by using a modified Sawyer-Tower circuit (Precision Premier II, Radiant Technologies, Inc.). The piezoelectric coefficient d₃₃ was measured by using a YE 2730A d₃₃-meter (APC Products, Inc., Pleasant Gap, Pa.).

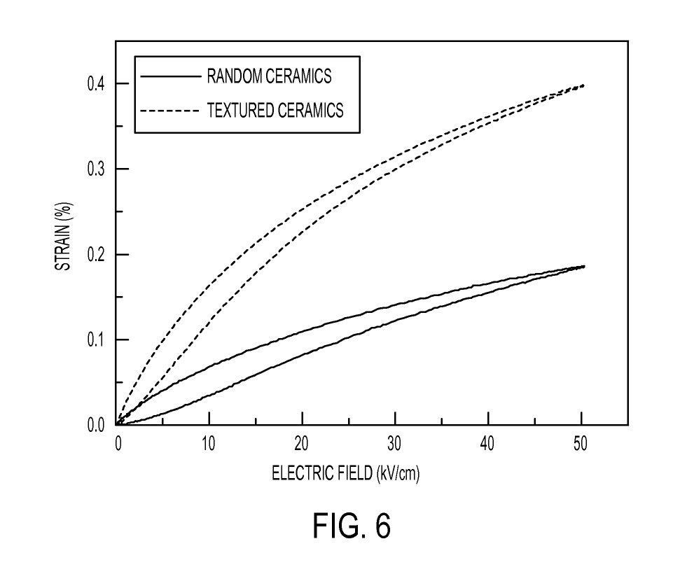

FIG. 6 shows strain as a function of electric field for both random and textured ceramics. As shown, strain increases much more rapidly for textured ceramics than for random ceramics.

A variation of the first preferred embodiment will now be set forth. The variation allows improvement in both the hard characteristics and the soft characteristics.

In this variation, we selected a 0.4Pb(Mg_{1/3}Nb_{2/3})O₃-0.25PbZrO₃-0.35PbTiO₃ (PMN-PZT) composition as the baseline since it has relatively high rhombohedral to tetragonal (R—T) transition temperature (T_{R-T} of 160° C.) and Curie temperature (T_{C} of 234° C.) compared to those of PMN-PT. This composition was then modified by Mn-doping and textured using BaTiO₃ templates to achieve superior performance with temperature stability.

1 mol. % MnO, doped PMN-PZT ceramic was textured by the TGG method with BaTiO, (BT) template crystals using tape casting and sintering as described above. For comparison, randomly oriented pure PMN-PZT and 1 mol. % MnO, doped PMN-PZT were also synthesized by using the same process without employing the BT template. The structural properties of samples were determined using x-ray diffraction (XRD, PANalytical X'Pert, CuKα, Philips, Netherlands) and scanning electron microscopy (SEM, FEI Quanta 600 FEG, Philips). The degree of pseudo-cubic <001> texturing of samples was determined by the Lotgering factor method. The dielectric constant (∈₃₃^{T}/∈₀) and tan δ of poled samples was measured as a function of temperature by using a multi-frequency LCR meter (HP4274A, Hewlett-Packard Development Company, CA). Pyroelectric current was measured as a function of temperature by using a pA meter (HP 4140B, USA). The piezoelectric properties of samples were obtained by resonance and anti-resonance technique using impedance/gain phase analyzer (HP 4194A, Hewlett-Packard Development Company) and d₃₃-meter (YE 2730 A, APC Products, Inc., PA).

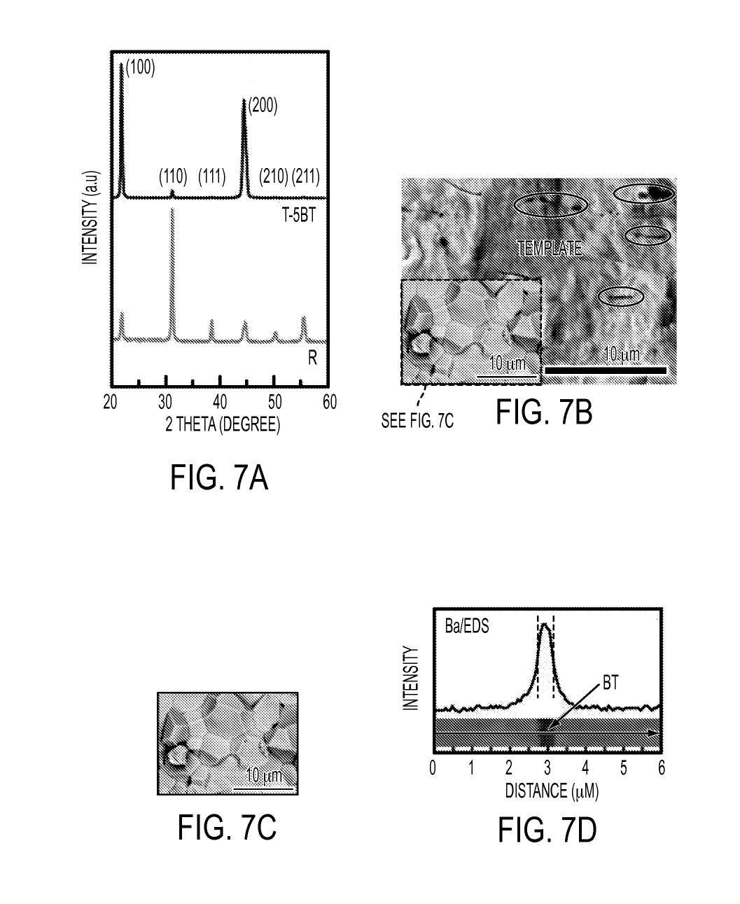

FIG. 7A shows the XRD patterns of randomly oriented and textured MnO-doped PMN-PZT ceramics with 5 vol. % BT (R and T-5BT ceramics, respectively). All the samples showed perovskite structure. Compared to the R ceramic, the 001 reflection peaks of T-5BT ceramic were enhanced, exhibiting high Lotgering factor of 96%, which indicates a strong pseudo-cubic <001> orientation of textured grains in the T-5BT ceramic. The SEM image of the T-5BT ceramic showed a brick wall-like microstructure with well aligned BT templates (black lines) in the matrix, as shown in FIG. 7B, while the R ceramics showed homogeneous equiaxed grains (FIG. 7C).

Table 2 shows the dielectric and piezoelectric properties of randomly oriented pure PMN-PZT (R-pure ceramic), R ceramic, and T-5BT ceramic poled and measured at room temperature. The piezoelectric properties of T-5BT ceramic were enhanced compared to those of R-pure and R ceramics. Note that the Qₘ and tan δ of the T-5BT ceramic were improved together with the d and k coefficients clearly demonstrating presence of “hard” and “soft” combinatory characteristics. Both d₃₃ and Qₘ of the T-5BT ceramic were 4 times higher and tan δ was 6.5 times lower than those of R-pure ceramic. This result confirms that the combination of texturing and Mn-doping is effective for developing high power piezoelectrics.

TABLE 2
Dielectric and piezoelectric properties of randomly oriented pure
PMN-PZT, randomly oriented, and textured MnO₂ doped PMN-PZT ceramics
(abbreviated as R-pure, R, and T-5BT, respectively)

| | | tan δ | d₃₃ | D₃₁ | | g₃₃ | g₃₁ | | Tₘ |
|---|---|---|---|---|---|---|---|---|---|
| Properties | ∈₃₃^{T}/∈₀ | (%) | (pC/N) | (pC/N) | k₃₁ | (10⁻³ Vm/N) | (10⁻³ Vm/N) | Qₘ | (° C.) |
| R-pure | 915 | 1.9 | 230 | −78 | 0.27 | 28 | −9.6 | 102 | 234 |
| R | 765 | 0.32 | 180 | −69 | 0.27 | 27 | −10 | 747 | 225 |
| T-5BT | 1723 | 0.29 | 680 | −230 | 0.52 | 45 | −15 | 428 | 198 |

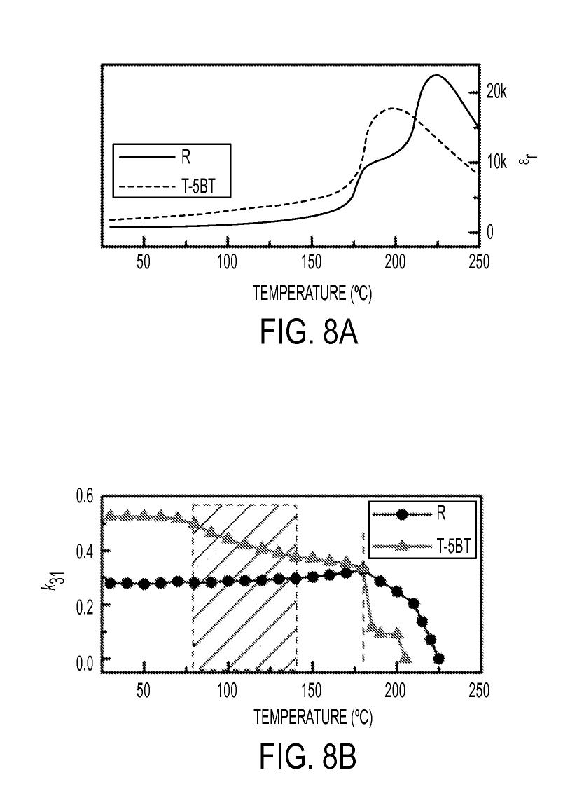

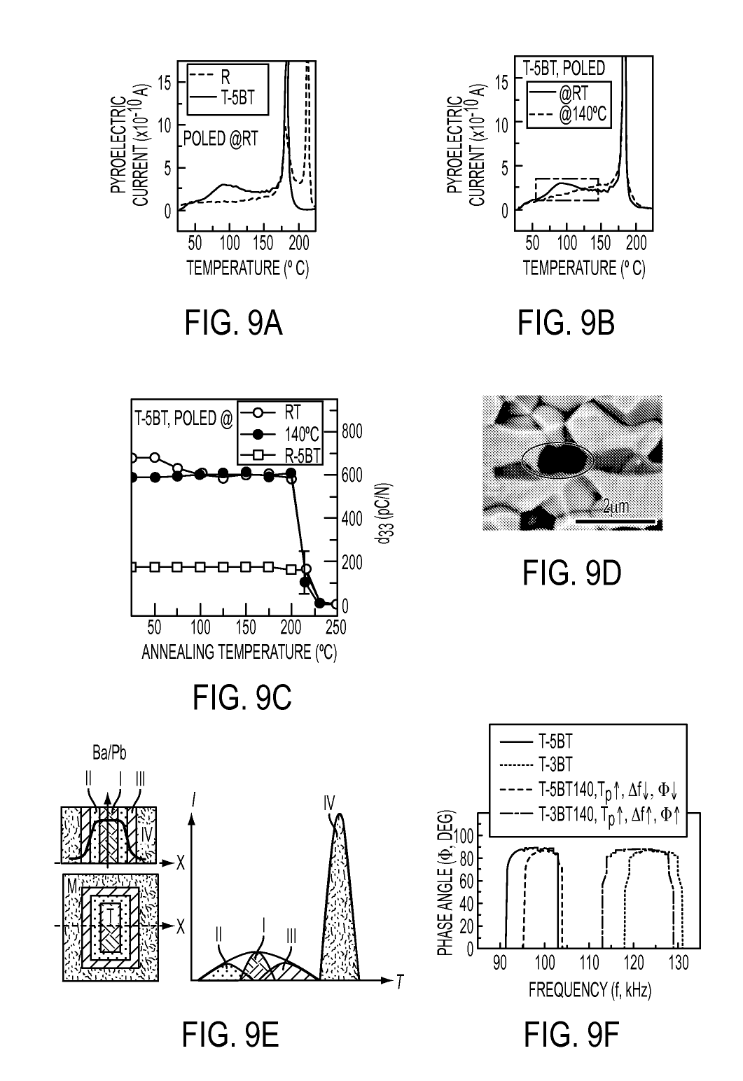

FIG. 8A shows the dielectric permittivity as a function of temperature for random and textured Mn doped PMN-PZT ceramics. There are two obvious peaks for random ceramics located at ˜180° C. and 225° C. The first dielectric anomaly is the rhombohedral to tetragonal phase transformation temperature (T_{R-T}), while the second one is related to the Curie temperature (T_{C}). For textured ceramics, there is only one obvious peak located at 198° C. attributed to T_{C}. The decrease of T_{C} is due to the existence of low T_{C} BT template indicating shift in the composition towards rhombohedral side. Several other studies have reported that T_{C} of textured PMN-PT ceramics is decreased due to the existence of heterogeneous templates (such as BaTiO₃, SrTiO₃). In case of SrTiO₃ textured PMN-PT, the depolarization temperature was unacceptably low (˜60° C.). In contrast, the T_{C} of T-5BT textured ceramics was still high on the order of 198° C. However, we found that T-5BT ceramic has problem related to temperature stability of piezoelectric properties. As can be seen in FIG. 8B, the k₃₁ of T-5BT ceramic started to degrade from 75° C., while the R ceramic showed a stable tendency up to 180° C. (T_{R-T} of R ceramic). In order to understand this problem, we first analyzed the spontaneous polarization of T-5BT ceramic to precisely confirm the contribution of R-T transition. The pyroelectric current (I_{P}) of the ferroelectrics under variation of temperature is given as I_{P}=(dPₛ/dT)·(dT/dt), where Pₛ is spontaneous polarization, T is temperature, and t is time. Usually, the I_{P} of ferroelectrics shows a sharp increase at phase transition temperatures (e.g., at T_{R-T} and T_{C} of R ceramic as shown in FIG. 9A). The T-5BT ceramic also exhibited a sharp I_{P} peak at 180° C.; however, there was another broad peak in the range 75-140° C. There was no obvious T_{R-T} peak of T-5BT ceramic in FIG. 8A; therefore, this peak was not associated with the rhombohedral-tetragonal phase transition. FIG. 9B shows the I_{P} vs. temperature curve of the T-5BT ceramic poled at 140° C. It can be clearly seen in this figure that broad peak found in FIG. 9A in the region 75-140° C. has vanished. Since the T_{C} of BT is 120° C., the BT template in T-5BT ceramic could be depoled at higher temperature. However, starting temperature of degradation was much lower than 120° C. as seen in FIG. 8B and more obvious in the d₃₃ plot shown in FIG. 9C. This result indicates that the depoling of BT templates is not the sole reason for electromechanical degradation and broad peak in the FIG. 9A and gave us insight to consider the role of template and template-matrix interface.

Although BT is quite stable in textured PMN-PT ceramic, it is known to dissolve in PZT ceramics. In the case of PMN-PZT, we investigated the microstructure of T-5BT ceramic in detail and found that some of the porous BT templates were partially dissolved during the texturing process (FIG. 9D). FIG. 9E schematically illustrates the concentration gradient that exists in the vicinity of the template—matrix interface using the microstructure and EDS analysis. There are four distinct regions in this diagram. Region I corresponds to the pure BT template, region II corresponds to the diffused area with high Ba/Pb concentration, region III corresponds to the region with slightly lower concentration ratio of Ba/Pb, and region IV represents pure matrix composition or no Ba. The diffusion of Ba into the matrix was confirmed from EDS line scanning data (FIG. 7D) showing that “interface region” with the width of ˜1 μm was formed in the vicinity of the BT template. The interface region could have composition corresponding to mixture of perovskites (Pb, Ba)[(Mg_{1/3}Nb_{2/3}),Zr,Ti)]O₃ and the T_{C} of the interface region can be lowered depending upon the concentration of Ba. All the component systems corresponding to PMN, BMN, BZ have been shown to have much lower T_{C} than BT. Thus, the variation of Ba/Pb concentration across this interface region results in the wide de-poling temperature range which explains the broad pyroelectric current peak in FIG. 8A as schematically depicted in FIG. 9E. Therefore, the degradation between 75 to 140° C. can be associated with the depoling of template which has lower paraelectric-ferroelectric transition temperature and the formation of interface region.

In this scenario, the piezoelectric properties of the system can be controlled by: (i) lowering the template content and (iii) poling the ceramic at temperatures higher than T_{C} of template and interface region. Based on this hypothesis, the content of BT template was decreased to reduce the interface volume in the ceramic and poling temperature was increased to 140° C. FIG. 9F shows the effect of the poling temperature and template content. A much higher degree of poling was found in the T-3BT ceramic poled at 140° C. confirming our hypothesis.

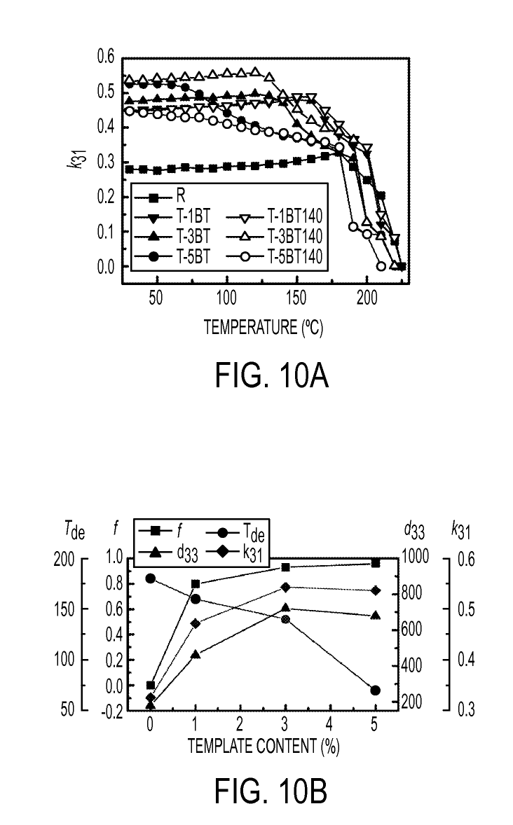

FIG. 10A shows the k₃₁ vs. temperature curves of MnO₂ doped PMN-PZT ceramics textured with 1, 3, and 5 vol. % BT and subsequently poled at 140° C. (T-1BT140, T-3BT140 and T-5BT140 ceramics, respectively). The T-5BT140 ceramic showed a gradual declining tendency in k₃₁ even though the degradation slope was decreased as compared to that of T-5BT ceramic, illustrating the significance of Ba diffusion and formation of the interface region. However, the 3BT140 ceramic exhibited quite stable and high k₃₁ (>0.53) in a wide temperature range from room temperature to 130° C. This result confirms that as the volume of interface region which has low T_{C} and relatively poor piezoelectricity was decreased by decreasing the BT content, an improved k₃₁ with high degradation temperature (T_{de}) was obtained. Furthermore, there was no obvious change in k₃₁ around 120° C. indicating that the formation of interface region is dominant factor in the degradation rather than the depoling of pure BT template. In the case of T-1BT140 ceramic, the T_{de} was increased up to 160° C. due to further reduced volume of interface region; however, the k₃₁ value was decreased because of low texture degree (Lotgering factor of 80%) as shown in FIG. 10B.

Table 3 lists the dielectric and piezoelectric properties of representative textured perovskite piezoelectric ceramics. Prior research has mostly focused on texturing “soft” piezoelectric compositions in order to improve d₃₃. Recently, results on Mn-doped PMN-PT textured ceramics were reported demonstrating good piezoelectric properties along with improved Qₘ (d₃₃=517 pC/N, k₃₁=0.44, Qₘ=714, tan δ=0.5%, and T_{de}=75° C.). In comparison, the 3BT140 ceramic synthesized in this study exhibited excellent “hard” and “soft” combinatory piezoelectric properties of d₃₃=720 pC/N, k₃₁=0.53, Qₘ=403, tan δ=0.3%, along with good temperature stability (T_{de}=130° C.).

In summary, we investigated the piezoelectric properties of textured MnO₂ doped PMN-PZT ceramics. The combination of texturing and hardening effect was confirmed to be suitable for developing high power piezoelectric materials possessing excellent “hard and soft” combinatory characteristics. The effect of template content on temperature stability of piezoelectric properties was investigated. The results show that the content and chemical stability of BT template significantly affects the piezoelectric properties and temperature stability of PZT-based textured ceramics. Mn-doped PMN-PZT textured ceramics containing 3 vol % BT exhibited excellent piezoelectric properties d₃₃=720 pC/N, k₃₁=0.53, Qₘ=403, tan δ=0.3% along with good temperature stability (T_{de}=130° C.).

TABLE 3
Dielectric and piezoelectric properties of representative textured perovskite ceramics

| | | F | T_{C} | T_{de} | d₃₃ | | | tan δ |
|---|---|---|---|---|---|---|---|---|
| Composition | Template | (%) | (° C.) | (° C.) | (pC/N) | k₃₁ | Qₘ | (%) |
| BNT-BT | Bi₄Ti₃O₁₂ | 96 | 260 | — | 241 | — | — | — |
| KNNS | NaNbO₃ | 98 | 353 | 160 | 208 | 0.37 | — | 1.8 |
| KNN (LF4) | NaNbO₃ | 91 | 253 | — | 416 | — | — | — |
| Ba(Zr_{0.085} Ti_{0.915})O₃ | 5 vol. % SrTiO₃ | >90 | 95 | — | 975 | — | — | — |
| PMN-32.5PT | 5 vol. % BaTiO₃ | 90 | 165 | — | 1150 | 0.484 | — | 1.3 |
| PMN-32PT | 5 vol. % BaTiO₃ | 97 | 147 | — | 877 | — | — | — |
| PMN-32.5PT | 5 vol. % SrTiO₃ | 69 | 120 | 60 | 1660 | — | — | 2 |
| PMN-34.5PT | PMN-PT | 95 | 161 | — | 660 | 0.44 | 110 | — |
| PMN-25PT | 7 vol. % NBT-0.6PT | 92 | 129 | 60 | 852 | 0.54 | 94 | 1.0 |
| 2% Mn + PMN-25PT | 7 vol. % NBT-0.6PT | 49 | 130 | 75 | 517 | 0.44 | 714 | 0.5 |
| 1% Mn + PMN-PZT | 3 vol. % BaTiO₃ | 93 | 210 | 130 | 720 | 0.53 | 403 | 0.3 |

A second preferred embodiment will now be disclosed. To reduce the adverse effect of heterogeneous template on the property of textured ceramics, it is important to reduce the concentration of heterogeneous template. In previous studies, normally, 5 vol. % template was added to achieve >90% texture degree and enhancement in the piezoelectric properties. In the second preferred embodiment, we quantify the effect of BT template concentration on the texture degree and the resulting changes in the properties of PMN-PT and show that even 1 vol. % template can provide >90% texture degree. Next, we model the response of the textured ceramics by deriving the change in free energy as a function of applied electric field and microstructural inhomogeneity. The model clearly revealed the effect of composite structure and clamping, validating the experimental results.

0.675Pb(Mg_{1/3}Nb_{2/3})O₃-0.325PbTiO₃ ceramics were textured by the TGG process using x vol. % of BaTiO₃ template, abbreviated as PMN-PT-xBT (x=0, 0.5, 1, 3, 5). The TGG process and the synthesis of the BT template have been described above. The texture degree was calculated from x-ray diffraction data (XRD, PANalytical X'Pert) by the Lotgering factor method. The microstructure was observed by using scanning electron microscopy (SEM, FEI Quanta 600 FEG). The relative permittivity (∈ᵣ) and loss (tan δ) were measured by using a multi-frequency Inductance-Capacitance-Resistance (LCR) meter (HP4287A). The electromechanical coupling factor was obtained by an impedance/gain analyzer (HP4194A). The piezoelectric coefficient d₃₃ was measured by using a YE 2730 A d₃₃-meter (APC Products, Inc.). The polarization vs. electric field hysteresis curves were measured by using a modified Sawyer-Tower circuit (Precision Premier II).

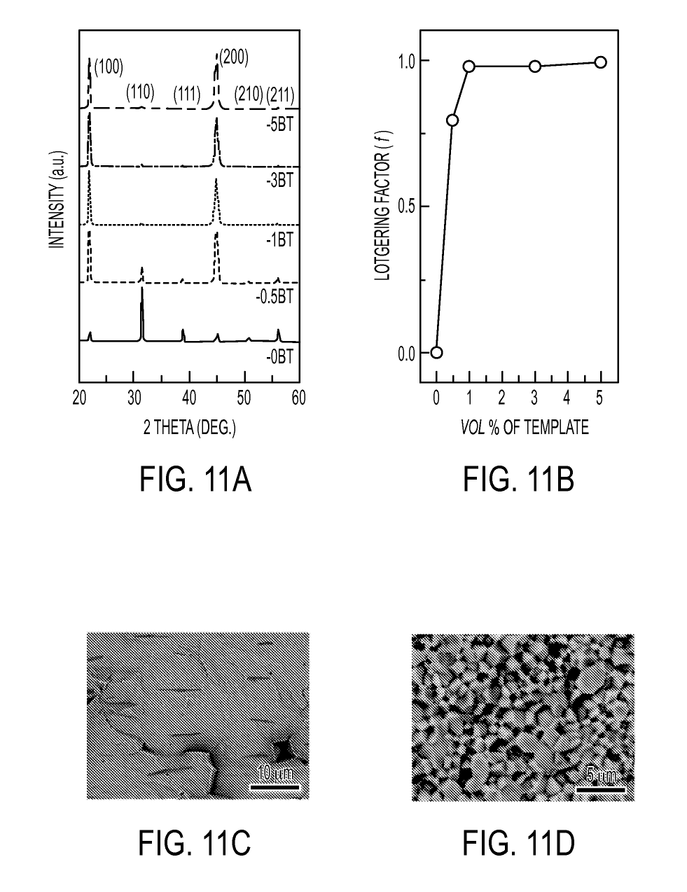

FIG. 11A shows the XRD patterns of PMN-PT-xBT sintered specimens. All patterns display pervoskite structure without any noticable secondary phase. With the introduction of templates, intensities of (001) peaks increase rapidly while other peaks show significantly reduced intensity, indicating the formation of texture. FIG. 11B shows the texture degree computed by the Lotgering factor method as a function of BT concentration. PMN-PT-0BT represents the random polycrystalline ceramics. With increase of BT template content, the texture degree increases dramatically and then saturates for PMN-PT-1BT. FIG. 11C displays the cross-sectional SEM image of the PMN-PT-1BT specimen. It shows brick wall-like structure. BT templates (black lines) were well aligned in the matrix, and there were almost no residual random-oriented matrix grains contrary to PMN-PT-0BT as shown in FIG. 11D. This microstructure is consistent with the high texture degree as indicated by XRD. These results clearly show that PMN-PT-1BT with 1 vol. % template was almost fully textured (f=0.98). This is a significant achievement with important implications towards application of piezoelectric ceramics. We found that the optimum dimension for BT template microcrystals to achieve high texture degree was in the vicinity of length: 5˜10 μm and thickness: 0.5˜1 μm. At these dimensions, the required growth distance for inducing texture in the matrix is dramatically reduced on the order of ˜3-7 μm.

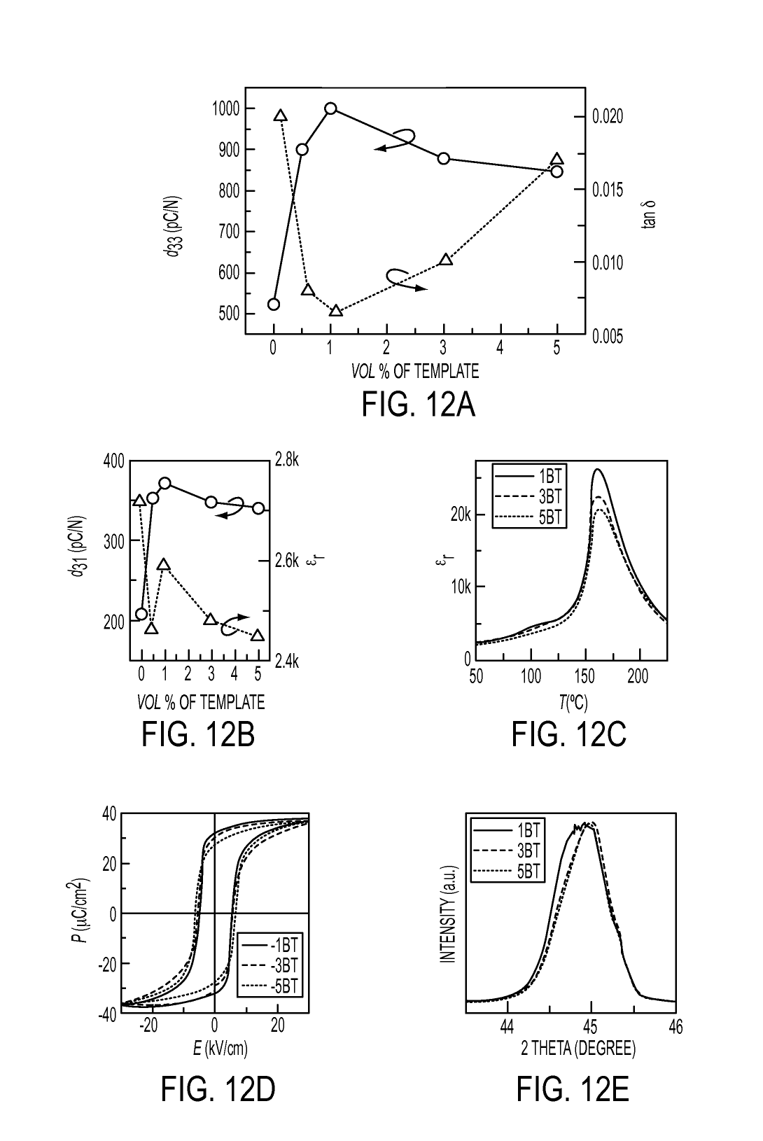

FIG. 12A shows the piezoelectric coefficient (d₃₃) and dielectric loss (tan δ) of PMN-PT-xBT specimen. With an increase of BT content, the d₃₃ increases dramatically and achieves the maximum value of 1000 pC/N at x=1, corresponding to the texture development as shown in FIG. 11B. In this range (0≦x≦1), the enhancement of piezoelectric response is attributed to the texture engineering which develops domain configurations similar to that in the single crystal. Further increasing the BT content, the d₃₃ gradually decreases. Similar trend can also be observed in the change of d₃₁ as shown in FIG. 12B. On the other hand, variation in tan δ is contrary to that for d₃₃. The lowest value of tan δ (˜0.6%) was achieved for PMN-PT-1BT ceramic, which is about ⅓rd of the magnitude obtained for most of the soft piezoelectric ceramics (>2.0%). High piezoelectric response with low loss makes PMN-PT-1BT system an ideal substitute for currently deployed soft piezoelectrics.

In spite of the increasing degree of texture, the decrease in d₃₃ for x>1 samples can be understood by considering Eq. (4), relating piezoelectric coefficient d₃₃ with electrostrictive constant Q₁₁, relative permittivity (δᵣ), and remnant polarization (Pᵣ),

d₃₃=2Q₁₁∈₀∈ᵣPᵣ (4).

Since the relative permittivity for the poled PMN-PT-xBT at room temperature decreases with x for x>1 (FIG. 12B), it can account for a decrease in d₃₃ values. The same tendency of maximum relative permittivity for unpoled PMN-PT-xBT can be found in FIG. 12C. It should be noted here that no obvious T_{c} shift in PMN-PT-xBT specimen indicates BT is very stable in PMN-PT ceramics, which is different from SrTiO₃ textured PMN-PT ceramic. Therefore, the decrease of ∈ᵣ may be associated with the elastoelectric composite effect due to the introduction of low permittivity BT template (∈ᵣ=130 in the <001> direction). FIG. 12D shows the polarization (P) vs. electric field (E) for the PMN-PT-xBT specimen in the range of x>1. It can be seen that Pᵣ decreases and the coercive field (E_{c}) increases with increasing BT template content (x), which indicates that the domain motion and switching became more difficult. This phenomenon may be attributed to clamping effect of BT template. The stress comes from the lattice mismatch between BT template and PMN-PT matrix and also from their large difference in electromechanical properties. Sabolsky has shown that this stress is high enough to depole the textured PMN-PT ceramic at large dimensions (˜100 μm) of the BT template. The stress build-up also results in phase shift from rhombohedral side to tetragonal side. In our study, fine BT template crystals were used which reduces the magnitude of stress. Even then, as shown in FIG. 12E, the width of (002) peaks decreases indicating phase shift from the morphotropic phase boundary (MPB) (coexistence of rhombohedral and tetragonal phase) to the tetragonal side. Therefore, elastoelectric composite effect and clamping effect can be suggested to degrade the piezoelectric property when texture degree saturates.

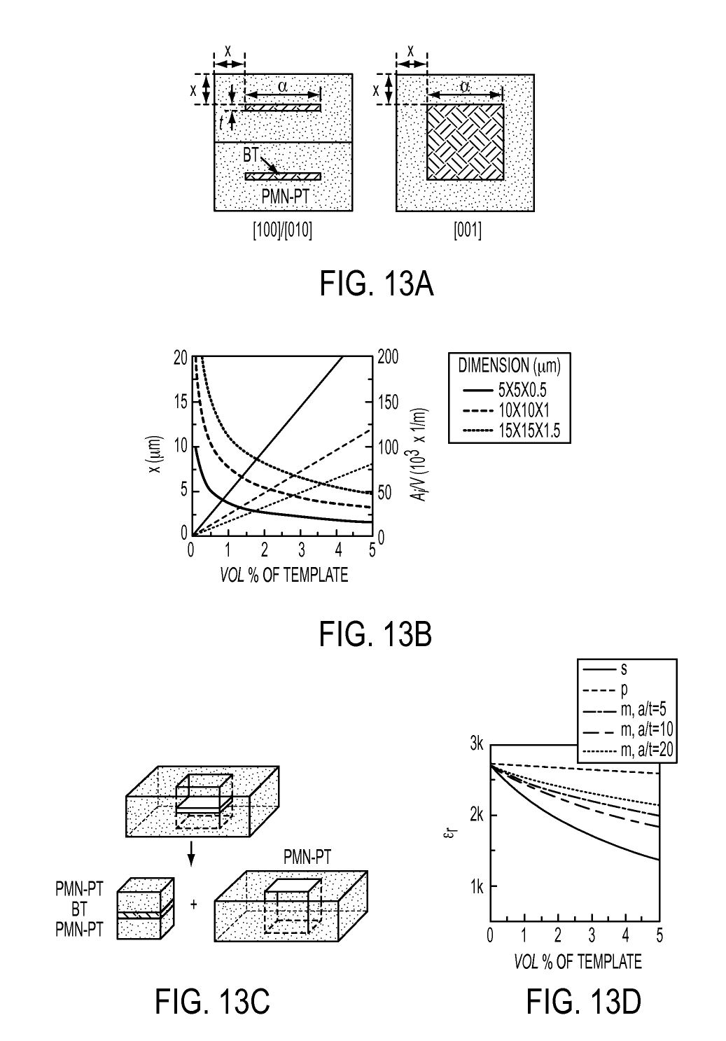

Textured PMN-PT ceramics can be considered as a composite consisting of matrix PMN-PT and BT templates, as shown in FIG. 13A. In ideal condition, the required growth distance (x) of PMN-PT crystal on BT template for 100% texture degree can be calculated by the following equation:

$$\frac{{a}^{2} T}{{V}_{T}} = {( 2 x + a )}^{2} ( 2 x + t ) , \qquad ( 5 )$$

where a is the dimension of the template plane, t is the thickness of the template, and V_{T} is the volume fraction of template. FIG. 13B shows the variation of x as a function of the volume fraction and dimensions of template. The higher the template content, the shorter the growth distance; thus, it is easier to achieve full texture. As shown in FIG. 13C, this composite can be considered as both parallel and series connections between the PMN-PT matrix and the BT template. In these two cases, effective permittivity of composite can be given by Eqs. (6, 7), respectively,

$$\begin{matrix}{ɛ}_{parallel} = {ɛ}_{t} {V}_{T} + {ɛ}_{m} ( 1 - {V}_{T} ) , & ( 6 ) \\ {ɛ}_{serial} = [ \frac{{ɛ}_{t} {ɛ}_{m}}{{ɛ}_{m} {V}_{T} + {ɛ}_{t} ( 1 - {V}_{T} )} ] , & ( 7 )\end{matrix}$$

where ∈ₘ and ∈ₜ are the relative permittivity of the PMN-PT matrix and the BT template, respectively. Since the textured sample is composed of both parallel and serial connection between PMN-PT matrix and BT templates (FIG. 13C), the relative permittivity of this composite structure (∈_{mixed}) was calculated by the following expression:

$${ɛ}_{mixed} = [ \frac{{ɛ}_{m} \frac{4 {x}^{2} + 4 ax}{2 x + t} + \frac{{a}^{2} {ɛ}_{t} {ɛ}_{m}}{2 x {ɛ}_{m} + t {ɛ}_{t}}}{\frac{{( 2 x + a )}^{2}}{2 x + t}} ] . \qquad ( 8 )$$

FIG. 13D shows the theoretical relative permittivity for 100% textured ceramics as a function of the volume fraction and dimensions of template. Here, the relative permittivity is calculated from Eqs. (6)-(8) by using ∈ₘ=2718 for PMN-PT matrix grains and ∈ₜ=130 for the <001> BT template.

As shown in FIG. 13B, the specific interface area (Aᵢ/V) related to the clamping effect increases linearly with the BT template content. To further clarify the clamping effects of the BT template content, texture degree, and material property mismatches between PMN-PT and BT on the dielectric and piezoelectric properties of the textured PMN-PT ceramics, we modeled the electrical behavior of the system by accounting the microstructural boundary conditions. The total free energy F of matrix-template composite system under externally applied electric field E^{ex} is given as

$$F = \int {d}^{3} r [ \frac{{P}^{2} ( r )}{2 {ɛ}_{0} χ ( r )} - {E}_{k}^{ex} {P}_{k} ( r ) ] + \frac{1}{2} \int \frac{{d}^{3} k}{{( 2 π )}^{3}} [ \frac{{n}_{i} {n}_{j}}{{ɛ}_{0}} {\tilde{P}}_{i} {\tilde{P}}_{j}^{*} + {K}_{ijkl} {\tilde{ɛ}}_{ij} {\tilde{ɛ}}_{kl}^{*} ] , \qquad ( 9 )$$

where ∈₀ is the permittivity of free space, χ(r) is the phase-dependent dielectric susceptibility that describes the composite microstructure, \tilde{P}(k) is the Fourier transform of the polarization field P(r), n=k/k is a unit directional vector in k-space, Kᵢⱼₖₗ combines elastic constants and serves as an effective elastic stiffness tensor, and \tilde{∈}(k) is the Fourier transform of the electrostrictive strain field ∈(r). The r-space integral in Eq. (9) describes the dielectric response of individual phases in the composite under electric field, and the k-space integral describes the electrostatic and elastic energies, respectively, due to inhomogeneous polarization distribution in the composite and mechanical clamping between the matrix and templates. While Eq. (9) can be numerically solved to perform large-scale computer simulation studies, it can be analytically simplified in the case of the textured PMN-PT ceramics based on the specific microstructure morphology as observed from the SEM image of FIG. 11C: BT platelet templates exhibit high aspect ratio (ρ=a/t˜10), are well dispersed in the matrix with large separation distance at low volume fraction (V_{T}<5%), and are aligned parallel to tape plane via tape casting. In such a situation, the k-space integrals in Eq. (9) can be analytically integrated for platelets, and the energy density (per unit volume) of the composite under external electric field applied normal to the template platelets becomes

$$F ( {P}_{T} , {P}_{{M}^{′}} , {P}_{{M}^{″}} , {E}^{es} ) = {V}_{T} \frac{{P}_{T}^{2}}{2 {ɛ}_{0} {χ}_{T}} + {V}_{{M}^{′}} \frac{{P}_{{M}^{′}}^{2}}{2 {ɛ}_{0} {χ}_{M}} + {V}_{{M}^{″}} \frac{{P}_{{M}^{″}}^{2}}{2 {ɛ}_{0} {χ}_{M}} + \frac{{V}_{T} {V}_{{M}^{′}}}{{V}_{T} + {V}_{{M}^{′}}} \frac{{( {P}_{T} - {P}_{{M}^{′}} )}^{2}}{2 {ɛ}_{0} {χ}_{0}} + \frac{{V}_{T} {V}_{{M}^{′}}}{{V}_{T} + {V}_{{M}^{′}}} \frac{{Y [ {b}_{31}^{T} - {b}_{31}^{M} {P}_{{M}^{′}} ]}^{2}}{1 - v} - ( {V}_{T} {P}_{T} + {V}_{{M}^{′}} {P}_{{M}^{′}} + {V}_{{M}^{″}} {P}_{{M}^{″}} ) {E}^{ex} . \qquad ( 10 )$$

In arriving at Eq. (10), the composite volume is approximately separated into three parts of volume fractions V_{T}, V_{M′}, and V_{M″}, respectively, where V_{T} is BT template volume fraction, V_{M′}≈ρV_{T} is the volume fraction of PMN-PT matrix that is in parallel connection with BT platelets, thus is both mechanically clamped by the templates and electrostatically affected by the matrix-template interfacial charges, and V_{M″} (=1−V_{T}−V_{M′}) is the volume fraction of the rest PMN-PT matrix that is not affected by mechanical clamping or interfacial charges. Thus, Eq. (10) takes into account the mixed nature of both parallel and serial connections between PMN-PT matrix and BT templates in the composite. It is worth noting that the volume V_{M′}≈ρV_{T} is approximated using the template aspect ratio ρ (˜10) in accordance with Saint-Venant's principle that states internal fields diminish with distance comparable to heterogeneity dimensions, allowing simplification of the internal boundary conditions and analytical evaluation of the electrostatic and elastic energies in a template-matrix volume (V_{T}+V_{M′}) around the thin platelet inclusions. It must be noted that the result in Eq. (10) is valid only for composites of well dispersed platelet templates at low volume fraction (i.e., V_{T}<5%) and under external electric field applied normal to the template platelets (i.e., along tape thickness direction), as is the case here. In Eq. (10), P_{T}, P_{M′}, and P_{M″} are the polarizations induced by the external field E^{ex} in three respective volume parts, χ_{T}, χ_{M} and b₃₁^{T}, b₃₁^{M} are the dielectric susceptibilities and piezoelectric polarization coefficients of BT template and PMN-PT matrix, respectively, χ₀ is a background dielectric susceptibility attenuating electrostatic interactions, and Y and v are Young's modulus and Poisson's ratio, respectively. To predict the dielectric and piezoelectric responses of the composite, the values of P_{T}, P_{M′}, and P_{M″} are first obtained for nonzero field E^{ex} by solving,

$$\frac{\partial F}{\partial {P}_{T}} = 0 , \frac{\partial F}{\partial {P}_{{M}^{′}}} = 0 , \frac{\partial F}{\partial {PM}^{″}} = 0. \qquad ( 11 )$$

The dielectric susceptibility χ and piezoelectric strain coefficients d₃₃ and d₃₁ of the composite are then determined from the obtained P_{T}, P_{M′}, and P_{M″} according to expressions,

$$\begin{matrix}χ = \frac{{V}_{T} {P}_{T} + {V}_{{M}^{′}} {P}_{{M}^{′}} + {V}_{{M}^{″}} {P}_{{M}^{″}}}{{ɛ}_{0} {E}^{ex}} , & ( 12 ) \\ {d}_{33} = \frac{{V}_{T} {b}_{33}^{T} {P}_{T} + {V}_{{M}^{′}} {b}_{33}^{M} {P}_{{M}^{′}} + {V}_{{M}^{″}} {b}_{33}^{M} {P}_{{M}^{″}}}{{E}^{ex}} , & ( 13 ) \\ {d}_{31} = \frac{{V}_{T} {b}_{31}^{T} {P}_{T} + {V}_{{M}^{′}} {b}_{31}^{M} {P}_{{M}^{′}} + {V}_{{M}^{″}} {b}_{31}^{M} {P}_{{M}^{″}}}{{E}^{ex}} . & ( 14 )\end{matrix}$$

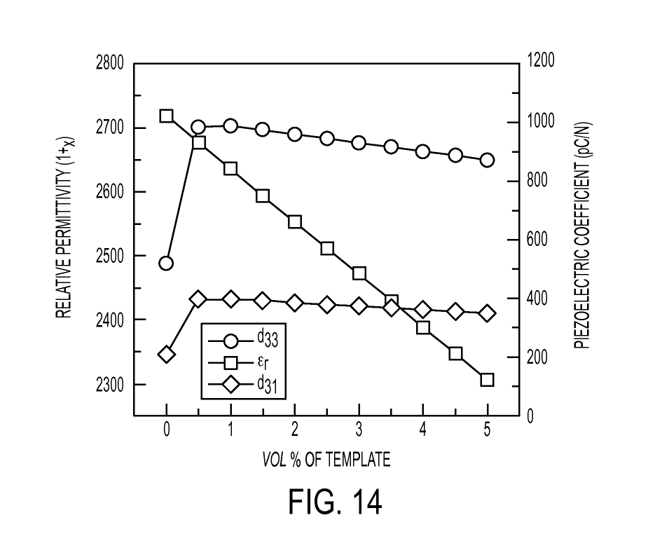

For calculations, the following material parameters were used:¹ χ_{T}=130, χ_{M}=2718, d₃₁^{T}=−33×10⁻¹² C/N, d₃₃^{T}=90×10⁻¹² C/N, d₃₁^{MR}=−210×10⁻¹² C/N, d₃₁^{MT}=−400×10⁻¹² C/N, d₃₃^{MR}=520×10⁻¹² C/N, d₃₃^{MT}=1000×10⁻¹² C/N, χ₀=1000, Y=100×10⁹ N/m², and v=0.3, where the superscripts MR and MT indicate random (non-textured) and fully [001]—textured PMN-PT matrix, respectively. The piezoelectric polarization b-coefficients are obtained from the piezoelectric strain d-coefficients from the relation b=(∈₀χ)⁻¹d for the corresponding constants of each phase. To capture the strong dependence of piezoelectric polarization coefficients of PMN-PT matrix on its texture due to the high anisotropy of PMN-PT single crystal, we use b^{M}=b^{MR}+f(V_{T})(b^{MT}−b^{MR}), where f(V_{T})=1-exp(−V_{T}/V₀) is a texture parameter function fitted to the Lotgering factor plotted in FIG. 11B, with fitting parameter V₀=0.003. The theoretically predicted dielectric and piezoelectric properties of textured PMN-PT ceramics are plotted as a function of BT template volume fraction in FIG. 14, exhibiting good agreement with the experimental measurements shown in FIGS. 12A and 12B, especially for the piezoelectric strain coefficients d₃₃ and d₃₁. These results confirm that [001] texturing of PMN-PT significantly improves the ceramic properties, while BT template content decreases the composite properties through mechanical clamping effect and interfacial mismatch.

In conclusion, we quantify the effect of BT template heterogeneity on the texture degree and piezoelectric properties of PMN-PT ceramics. The inhomogeneity effect (elastoelectric composite effect, clamping strain) was clarified by theoretical models. Almost full [001] texture (f=0.98) was achieved at a very low template volume fraction (1%). This is an important advancement in texture engineering of PMN-PT ceramics that promises to provide high-performance piezoelectric materials at significantly lower cost.

While two preferred embodiments and variations thereof have been set forth in detail above, those skilled in the art who have reviewed the present disclosure will readily appreciate that other embodiments can be realized within the scope of the invention. For example, numerical values are illustrative rather than limiting. Also, any materials having the appropriate physical properties (e.g., piezoelectric properties, stability, or lattice match) can be substituted for those disclosed. Therefore, the present invention should be construed as limited only by the appended claims.

We claim:

1. A textured PMN-PZT ceramic material comprising:
a plurality of seed crystals that are aligned in a common direction; and
a plurality of matrix crystals formed around the plurality of seed crystals, the plurality of matrix crystals comprising a PMN-PZT material.

2. The ceramic material of claim 1, wherein the plurality of seed crystals comprise a seed composition having a lattice match with the PMN-PZT material.

3. The ceramic material of claim 2, wherein the seed composition is BaTiO₃.

4. The ceramic material of claim 3, wherein:
the seed crystals have a platelet morphology with a (001) plane; and
the common direction is a [001] direction, whereby the ceramic material is a [001] textured ceramic material.

5. The ceramic material of claim 1, wherein the PMN-PZT material is Mn-doped.

6. A piezoelectric transducer comprising the ceramic material of claim 1.

7. A method for forming a textured PMN-PZT ceramic material, the method comprising:
(a) providing a plurality of seed crystals;
(b) aligning the seed crystals in a common direction; and
(c) forming a plurality of matrix crystals around the plurality of seed crystals, the plurality of matrix crystals comprising a PMN-PZT material.

8. The method of claim 7, wherein the plurality of seed crystals comprise a seed composition having a lattice match with the PMN-PZT material.

9. The method of claim 8, wherein the seed composition is BaTiO₃.

10. The method of claim 9, wherein step (a) comprises forming the seed crystals by a topochemical microcrystal conversion technique.

11. The method of claim 9, wherein:
step (a) comprises forming the seed crystals to have a platelet morphology with a (001) plane; and
in step (b), the common direction is a [001] direction, whereby the ceramic material is a textured ceramic material.

12. The method of claim 9, wherein step (b) comprises aligning the seed crystals in a ceramic matrix powder.

13. The method of claim 12, wherein step (b) comprises aligning the crystals using a tape-casting process.

14. The method of claim 12, wherein step (c) comprises sintering the ceramic matrix powder.

15. The method of claim 12, wherein the ceramic matrix powder is formed by:
(i) forming a mixture of (PbCO₃)₂Pb(OH)₂, Nb₂O₅, ZrO₂, TiO₂, ZnO, and MnO₂;
(ii) milling the mixture to form a milled mixture; and
(iii) calcining the milled mixture.

16. The method of claim 15, wherein the mixture is milled by ball-milling in ethanol and is then dried.

17. The method of claim 15, wherein the mixture is Mn-doped.

18. The method of claim 7, wherein step (c) comprises Mn-doping the matrix crystals.

19. A textured PMN-PT ceramic material comprising:
a plurality of BaTiO₃ seed crystals that are aligned in a common direction; and
a plurality of matrix crystals formed around the plurality of seed crystals, the plurality of matrix crystals comprising a PMN-PT material;
wherein the plurality of seed crystals make up no more than 1% by volume of the ceramic material.

20. The ceramic material of claim 19, wherein:
the seed crystals have a platelet morphology with a (001) plane; and
the common direction is a [001] direction, whereby the ceramic material is a [001] textured ceramic material.

21. A piezoelectric transducer comprising the ceramic material of claim 19.

22. A method for forming a textured PMN-PT ceramic material, the method comprising:
(a) providing a plurality of BaTiO₃ seed crystals;
(b) aligning the seed crystals in a common direction; and
(c) forming a plurality of matrix crystals around the plurality of seed crystals, the plurality of matrix crystals comprising a PMN-PT material;
wherein the plurality of seed crystals make up no more than 1% by volume of the ceramic material.

23. The method of claim 22, wherein step (a) comprises forming the seed crystals by a topochemical microcrystal conversion technique.

24. The method of claim 22, wherein:
step (a) comprises forming the seed crystals to have a platelet morphology with a (001) plane; and
in step (b), the common direction is a [001] direction, whereby the ceramic material is a textured ceramic material.

25. The method of claim 22, wherein step (b) comprises aligning the seed crystals in a ceramic matrix powder.

26. The method of claim 22, wherein step (b) comprises aligning the crystals using a tape-casting process.

27. The method of claim 22, wherein step (c) comprises sintering the ceramic matrix powder.
